(19) United States
(12) Patent Application Publication
(10) Pub. No.: US 2023/0384695 A1
(43) Pub. Date: Nov. 30, 2023

(54) RETICLE CONTAINER HAVING MAGNETIC PARTICLE CAPTURE

(71) Applicant: ENTEGRIS, INC., Billerica, MA (US)

(72) Inventors: Lesa Lindgren, Monument, CO (US); Russ V. Raschke, Chanhassen, MN (US)

(21) Appl. No.: 18/201,352

(22) Filed: May 24, 2023

Related U.S. Application Data
(60) Provisional application No. 63/346,736, filed on May 27, 2022.

(51) Int. Cl. G03F 7/20; G03F 1/66

(52) U.S. Cl. CPC G03F 7/70741; G03F 1/66; G03F 7/70925

(57) ABSTRACT

Reticle containers include a cover and a baseplate, with magnetic particle traps included in at least one of the cover or the baseplate. The cover and baseplate each include sealing surfaces, and at least one of the sealing surfaces includes magnetic material that can be attracted by the magnetic particle traps. The sealing surfaces can be selected such that particulate generated by wear at the sealing surfaces is primarily the magnetic material. The magnetic particle traps can further be configured to be cleaned by reduction of the attraction of the particulate matter to the magnetic particle traps.

### PRIORITY CLAIM

This disclosure claims priority to U.S. provisional patent No. 63/346,736 with a filing date of May 27, 2022, which is incorporated by reference herein.

### FIELD

This disclosure is directed to reticle containers configured to magnetically capture particulate matter.

### BACKGROUND

Reticle containers can include metal components which can be in contact with one another. Friction can cause the generation of metal particulate contamination where these metal components contact other parts of the reticle container. The metal particulate can be a contaminant adversely affecting reticles contained in the reticle containers, causing expensive losses and lowering yields for processing of reticles such as photolithographic processing, for example extreme ultraviolet (EUV) photolithography.

### SUMMARY

This disclosure is directed to reticle containers configured to magnetically capture particulate matter.

By using magnetic materials at the sealing surfaces of a cover and a baseplate of a reticle container, resulting particulate generated by contact at these sealing surfaces

In an embodiment, an article includes a reticle container that includes a cover including a cover sealing surface, a baseplate including a baseplate sealing surface, and one or more magnetic particle traps. Each magnetic particle trap including a magnet. The cover and the baseplate define an internal space configured to accommodate a reticle, and one or both of the cover sealing surface and the baseplate sealing surface include a magnetic material.

In an embodiment, an article includes a reticle container. The reticle container includes a cover including a cover sealing surface and a baseplate including a baseplate sealing surface. The cover and the baseplate define an internal space configured to accommodate a reticle. The reticle container further includes one or more magnetic particle traps disposed on or in the cover, the baseplate, or a combination thereof.

In an embodiment, the one or more magnetic particle traps include a plurality of depressions provided on one of the cover sealing surface or the baseplate sealing surface. In an embodiment, the other of the cover sealing surface or the baseplate sealing surface includes a plurality of projections, each projection configured to extend into one of the plurality of depressions.

In an embodiment, the cover includes one or more filter openings, and the one or more magnetic particle traps are each disposed at one of the one or more filter openings.

In an embodiment, the one or more magnetic particle traps are disposed within the internal space.

In an embodiment, at least one of the cover sealing surface and the baseplate sealing surface includes a magnetic material. In an embodiment, the magnetic material is included in a coating applied to the cover or the baseplate to form the cover sealing surface or the baseplate sealing surface.

In an embodiment, the magnetic particle traps are configured such that an attraction force between the magnetic particle trap and the cover or the baseplate is less than a weight of the baseplate.

In an embodiment, a method of containing a reticle includes placing the reticle in an internal space of a reticle container, the reticle container including a cover, a baseplate, and one or more magnetic particle traps each including a magnet, wherein the cover includes a cover sealing surface, the baseplate includes a baseplate sealing surface.

In an embodiment, the method further includes capturing magnetic particles at the one or more magnetic particle traps. In an embodiment, the method further includes cleaning the magnetic particle traps by reducing an attraction between the magnet of each of the one or more magnetic particle traps and the magnetic particles. In an embodiment, cleaning the magnetic particle traps further includes applying a flow of gas to the magnetic particle traps.

In an embodiment, one or both of the cover sealing surface and the baseplate sealing surface includes a magnetic material, and the magnetic particles result from wearing at the one or both of the cover sealing surface and the baseplate sealing surface including the magnetic material.

In an embodiment, the method further includes separating the cover and the baseplate by supporting the cover and allowing the baseplate to drop.

In an embodiment, a method of manufacturing a reticle container includes providing a cover having a cover sealing surface, providing a baseplate having a baseplate sealing surface, and providing one or more magnetic particle traps on or in the cover, the baseplate, or a combination thereof.

In an embodiment, the method further includes providing magnetic material at one or both of the cover sealing surface and the baseplate sealing surface. In an embodiment, the providing magnetic material at the one or both of the cover sealing surface and the baseplate sealing surface includes applying a coating containing the magnetic material to the one or both of the cover sealing surface and the baseplate sealing surface.

In an embodiment, the providing one or more magnetic particle traps includes providing a plurality of depressions in one of the cover sealing surface or the baseplate sealing surface and disposing a magnet in each of the plurality of depressions.

In an embodiment, the cover includes one or more filter openings, and providing the one or more magnetic particle traps includes disposing the each of the one or more magnetic particle traps at one of the one or more filter openings.

In an embodiment, providing the one or more magnetic particle traps includes disposing each of the one or more magnetic particle traps on a surface of the cover or the baseplate defining the internal space of the reticle container.

### DRAWINGS

FIG. 1 shows a reticle container according to an embodiment.

FIG. 2 shows a cover of a reticle container according to an embodiment.

FIG. 3 shows a baseplate of a reticle container according to an embodiment.

### DETAILED DESCRIPTION

This disclosure is directed to reticle containers configured to magnetically capture particulate matter.

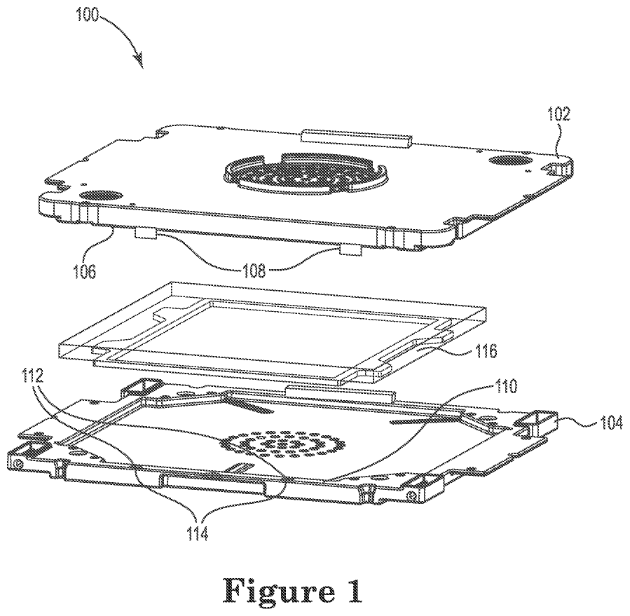

FIG. 1 shows a reticle container according to an embodiment. Reticle container 100 includes cover 102 and baseplate 104. Cover 102 includes cover sealing surface 106 and projections 108. Baseplate 104 includes baseplate sealing surface 110 and includes magnetic particle traps 112, which can optionally be disposed in recesses 114.

Reticle container 100 is a container configured to accommodate a reticle 116, for example during storage, transportation, or processing of the reticle. The storage, transportation, and/or processing of the reticle can be part of a process such as photolithography, for example extreme ultraviolet (EUV) photolithography.

Cover 102 forms part of reticle container 100. Cover 102 combined with baseplate 104 define an internal space capable of accommodating the reticle 116 to be contained within reticle container 100. Cover 102 includes cover sealing surface 106 at one or more positions of cover 102 configured to oppose or contact the baseplate 110. In an embodiment, the cover sealing surfaces 106 can include a magnetic material, for example nickel or any other material capable of being attracted by a magnetic field. Projections 108 can optionally be included in reticle container 100, for example in cover 102 extending from the cover sealing surface 106.

Baseplate 104 forms another part of reticle container 100. The baseplate 104 is configured such that when the baseplate 104 is combined with cover 102, an internal space capable of accommodating a reticle is defined. In an embodiment, the magnetic particle traps 112 can be included in the baseplate 104 instead of the cover 102 as described above. The baseplate 104 includes baseplate sealing surface 110 at one or more positions corresponding to the cover sealing surface 106. The baseplate sealing surface 110 can be configured to form a seal along with cover sealing surface 106, for example by contact between the cover and baseplate sealing surfaces 106, 110. Contact between cover and baseplate sealing surfaces 106, 110 can cause particles to be generated by friction wear of one or both of the cover and baseplate sealing surfaces 106, 110.

At least one of cover sealing surface 106 or baseplate sealing surface 110 can provide a magnetic material at the surface. The magnetic material can include any material capable of attraction to a magnet. The magnetic material may or may not itself be magnetized. In an embodiment, the magnetic material can include one or more of nickel, iron, cobalt, gadolinium, and the like. In an embodiment, the magnetic material at the surface of one or both of cover sealing surface 106 and baseplate sealing surface 110 can be magnetized such that the entire seal surface 106, 110 can serve at the magnetic particle trap 112. The magnetic material can be a coating applied at the at least one of cover sealing surface 106 or baseplate sealing surface 110, such as nickel plating applied to cover 102 or baseplate 104 at the corresponding sealing surface 106, 110. In an embodiment, both of cover sealing surface 106 and baseplate sealing surface 110 include magnetic material. In an embodiment, only one of the cover sealing surface 106 or the baseplate sealing surface 110 include magnetic material. In such an embodiment, the material of the one of cover sealing surface 106 or baseplate sealing surface 110 that is not the magnetic material can be selected such that wear from contact between the sealing surface 106 and 110 results in primarily particles of the magnetic material being generated. For example, when one of cover sealing surface 106 or baseplate sealing surface 110 is not the magnetic material, the material has a hardness greater than that of the magnetic material included at the other of the cover sealing surface 106 or baseplate sealing surface 110. In an embodiment, the difference in hardness between the non-magnetic material and the magnetic material can be at least 15 Rockwell C hardness. Non-limiting examples of non-magnetic materials that can be included at cover sealing surface or baseplate sealing surface 110 in some embodiments can include aluminum, titanium, molybdenum, and non-magnetic alloys or combinations thereof.

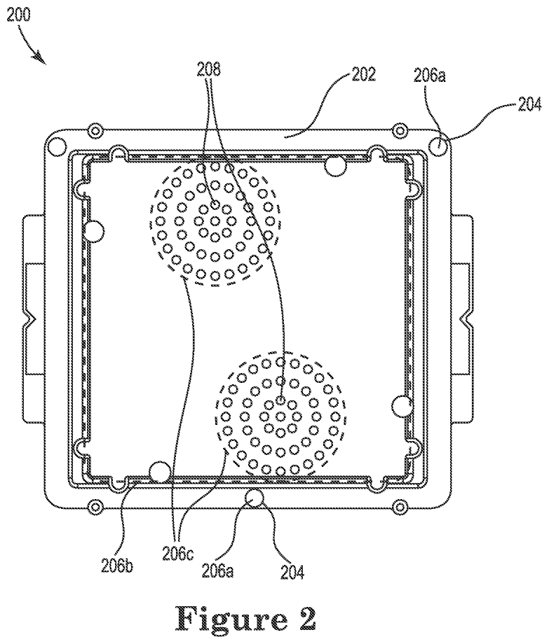

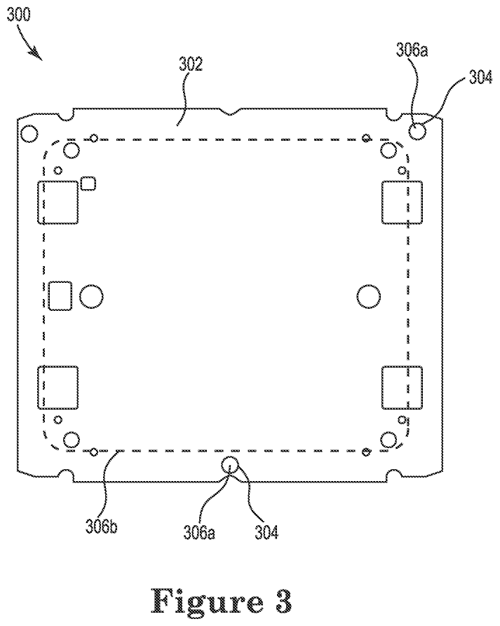

Magnetic particle traps 112 include a magnet configured to attract magnetic particles and capture said magnetic particles to reduce particulate within the internal space formed by cover 102 and baseplate 104. The magnetic particle traps 112 include a magnet configured to provide a magnetic field capable of attracting magnetic particles to the magnetic particle trap. The magnet can be any suitable magnet, such as permanent magnets. Non-limiting examples of such magnets include neodymium permanent magnets, samarium-cobalt magnets, or the like. The magnetic particles can be captured and held to the magnet by the field. The magnetic particle traps can be disposed in any suitable position on one or both of cover 102 and baseplate 104. Non-limiting examples of suitable positions for magnetic particle traps 112 on a cover such as cover 102 are shown in FIG. 2 and described below. Non-limiting example of suitable positions for magnetic particle traps 112 on a baseplate such as baseplate 104 are shown in FIG. 3 and described below. The magnetic particle traps 112 can further include additional structure, for example to position the magnet, direct flows that may carry particulate by the magnet, or any other suitable structure. In the embodiment shown in FIG. 1, the magnetic particle traps 112 are included as pucks or discs that are configured to be received in recesses 114. Magnetic particle traps 112 can be included in any suitable position and configuration where the magnetic particle traps can capture particulate matter prior to said particulate matter contacting a reticle contained within the internal space formed by cover 102 and baseplate 104. Other non-limiting examples of positions for the magnetic particle traps 112 include being provided on cover 102 just inside of the cover sealing surface 106, on or at an end of projections 108, at or near filter openings formed in cover 102, on baseplate 104 just inside of baseplate sealing surfaces 110, and the like. Magnetic particle traps 112 include one or more magnets that provide a magnetic field capable of attracting magnetic material included in one or both of the cover sealing surface 106 and the baseplate sealing surface 110. The magnet or magnets included in magnetic particle traps 112 can be selected such that the force of attraction between the magnetic particle traps and cover 102 and/or baseplate 104 is such that the attraction does not interfere with opening, closing, or other operation of reticle container 100. For example, the force of attraction can be less than a weight of the baseplate 104, such that the baseplate 104 can be dropped away from cover 102 to open the reticle container 100.

The magnetic particle traps 112 can be configured such that trapped particulate can be removed from the magnetic particle trap 112. The removal of trapped particulate can include a reduction in the extent to which the magnetic particle trap 112 attracts the particulate matter. The removal of trapped particulate can additionally or alternatively include application of a stream of gaseous or liquid fluid to drive out the trapped particles. As a non-limiting example, a gas such as nitrogen or clean dry air can be blown over the magnetic particle trap 112 to remove particulate. As another non-limiting example, a stream of liquid, such as deionized water, can be sprayed to remove particulate. In an embodiment, the magnetic particle traps 112 include electrical contacts capable of being energized to form an electromagnet such that the attraction of trapped particulate is reduced. In an embodiment, the magnetic particle traps 112 are configured to be placed within a magnet capable of providing a field capable of reducing the attraction of trapped particulate to the magnetic particle traps 112. In an embodiment, the magnetic particle traps 112 are removable from the cover 102 or the baseplate 104. In an embodiment, the entire cover 102 or baseplate 104 can be placed into a device including the magnet used to reduce attraction of particulate to the magnetic particle traps 112. In an embodiment, cleaning the magnetic particle traps 112 can include providing a stronger magnetic field to pull trapped particulate away from the magnetic particle traps 112 to the magnet applying said stronger magnetic field.

Recesses 114 can optionally be provided on baseplate 104, based on the position and/or the configuration of the magnetic particle traps 112. In an embodiment, the recesses 114 contain the magnetic particle traps 112, for example magnetic discs or pucks that are placed into the recesses 114. In an embodiment, the recesses 114 are configured to accommodate the projections 108 so as to allow assembly of cover 102 to baseplate 104. In embodiments where the projections 108 are instead provided on baseplate 104, the recesses 114 can instead be provided on cover 102 in positions corresponding to the projections 108. The recesses 114 can be omitted in embodiments where the magnetic particle traps 112 would not interfere with the interface of cover 102 and baseplate 104, or the accommodation of a reticle 116 within reticle container 100. In an embodiment, the recesses 114 can be configured such that cover sealing surface 106 and baseplate sealing surface 110 contact one another when the cover 102 and baseplate 104 are joined together. In an embodiment, the recesses 114 and the projections 108 can be configured to provide a gap between the cover sealing surface 106 and baseplate sealing surface 110 when the cover 102 and baseplate 104 are joined together.

FIG. 2 shows a cover of a reticle container according to an embodiment. Cover 200 includes cover sealing surface 202 and optionally projections 204. In an embodiment, cover 200 can include magnetic particle traps 206a, magnetic particle traps 206b, and/or magnetic particle traps 206c.

Cover sealing surface 202 is a portion of cover 200 configured to contact a baseplate when a reticle container including cover 200 is assembled. The cover sealing surface 202 can include a magnetic material at the surface, such that particles generated by wear of cover sealing surface 202 are capable of being attracted by a magnet included in a magnetic particle trap, such as magnetic particle trap 206a, b, or c. In an embodiment, the cover sealing surface 202 does not include a magnetic material. In such an embodiment, the baseplate includes the magnetic material at surfaces corresponding to cover sealing surface 202, and the cover sealing surface includes a material having a greater hardness than the magnetic material such that wear particles generated by friction including the cover sealing surface 202 includes predominantly the magnetic material. The magnetic material can, for example, include nickel.

In an embodiment, the cover 200 can include projections 204. The projections 204 extend from the cover sealing surface 202. The projections 204 can be positioned to extend into recesses formed in a baseplate used with cover 200 to form a reticle container. In an embodiment, a height of the projections is such that the cover sealing surface 202 contacts the baseplate when the reticle container including cover 200 is assembled. In an embodiment, a height of the projections 204 is such that the cover sealing surface 202 is spaced apart from a corresponding surface of the baseplate by a gap sized such that a pressure differential can be maintained for a period between an exterior and an interior of the reticle container. In an embodiment, the projections 204 can include a magnetic particle trap 206a. Magnetic particle trap 206a can optionally be provided as a coating on projections 204 and/or by providing a magnet at the tip of each of the projections 204. The magnetic particle trap 206a includes a magnet that provides a field capable of attracting magnetic particles such as particulate material generated by wear from friction involving the cover sealing surface 202. Magnetic particle trap 206a can further include, for example, a plating, coating, or other material containing the magnet.

In an embodiment, magnetic particle trap 206b can optionally be included in cover 200. Magnetic particle trap 206b can be provided in the internal space of the reticle container as defined by cover 200 and a corresponding baseplate. The magnetic particle trap 206b can be provided inside of cover sealing surface 202. In an embodiment, magnetic particle trap 206b is continuous about an interior perimeter of the cover sealing surface 202. In an embodiment, magnetic particle trap 206b includes one or more segments each extending corresponding to a portion of the interior perimeter of cover sealing surface 202. In an embodiment, magnetic particle trap 206b is applied as a coating. In an embodiment, magnetic particle trap 206b is attached through a mechanical connection and/or an adhesive. In an embodiment, magnetic particle trap 206b is level with adjacent surfaces of cover 200 inside of cover sealing surface 202. In an embodiment, magnetic particle trap 206b is disposed in a recess relative to adjacent surfaces of cover 200. In an embodiment, magnetic particle trap 206b can project relative to the adjacent surfaces of cover 200. Magnetic particle trap 206b can further include, for example, a plating, coating, or other material containing the magnet. In an embodiment, the magnetic particle trap 206b can be provided at some or all of the cover sealing surface 202. For example, a coating of the cover sealing surface 202 can be magnetized to provide magnetic particle trap 206b.

In an embodiment, magnetic particle trap 206c can optionally be included in cover 200. The magnetic particle trap 206c can be provided at or near filter openings 208. In an embodiment, the magnetic particle trap 206c surrounds a filter opening 208. In an embodiment, magnetic particle trap 206c is provided around a portion of filter opening 208. In an embodiment, the magnetic particle trap 206c is provided between at least two of filter openings 208. In an embodiment, the magnetic particle trap 206c is provided on a mesh over one or more of the filter openings 208. In an embodiment, magnetic particle trap 206c is applied as a coating. In an embodiment, magnetic particle trap 206c is attached through a mechanical connection and/or an adhesive. In an embodiment, magnetic particle trap 206c is level with adjacent surfaces of cover 200 at or near filter openings 208. In an embodiment, magnetic particle trap 206c is disposed in a recess relative to adjacent surfaces of cover 200. In an embodiment, magnetic particle trap 206c can project relative to the adjacent surfaces of cover 200. Magnetic particle trap 206c can further include, for example, a plating, coating, or other material containing the magnet.

When the optional magnetic particle traps 206a, b, and/or c are included in the cover 200, the attractive force of the magnetic particle traps 206a-c included in cover 200 can be selected such that the attractive force does not interfere with separation of cover 200 from a corresponding baseplate. For example, the attractive force between magnetic particle traps 206a-c and the baseplate can be less than a weight of the baseplate, such that the baseplate can separate from the cover 200 when cover 200 is being lifted or when support for the baseplate is removed while cover 200 is being retained in a tool.

FIG. 3 shows a baseplate of a reticle container according to an embodiment. Baseplate 300 includes baseplate sealing surface 302 and optionally recesses 304. In an embodiment, baseplate 300 can include magnetic particle traps 306a and/or magnetic particle traps 306b.

Baseplate sealing surface 302 is a portion of baseplate 300 configured to contact a corresponding surface of a cover used with baseplate 300 to provide a reticle container. The baseplate sealing surface 302 can include a magnetic material capable of being attracted by a magnetic field, such as a magnetic field provided by magnetic particle traps 206a-c as described above and shown in FIG. 2 or magnetic particle traps 306a or b. The magnetic material can be, as a non-limiting example, nickel. In an embodiment, baseplate sealing surface 302 does not include a magnetic material, but a corresponding surface of a cover being used with baseplate 300 does include magnetic material. In such an embodiment, a hardness of the baseplate sealing surface 302 can be greater than the hardness of the magnetic material such that particulate generated by friction involving the baseplate sealing surface 302 is predominantly the magnetic material.

Optionally, recesses 304 can be included in baseplate 300. In an embodiment, recesses 304 are included where a cover for use with baseplate 300 includes projections. The recesses 304 can be positioned to correspond to such projections from the cover, for example at particular locations along the baseplate sealing surface 302. In an embodiment, recesses 304 are sized such that corresponding projections can be received such that baseplate sealing surface 302 and a corresponding surface of the cover contact one another when the cover is assembled to baseplate 300. In an embodiment, recesses 304 are sized such that when projections from the cover are received in recesses 304, the baseplate sealing surface 302 is spaced apart from a corresponding surface of the cover by a gap sized such that a pressure differential can be maintained for a period between an exterior and an interior of the reticle container. In an embodiment, the recesses 304 can be trenches or grooves formed at or inside of baseplate sealing surface 302. The recesses 304 can be configured to receive particulate matter from outside of or at baseplate sealing surface 302.

Magnetic particle traps 306a can optionally be located in the recesses 304. The magnetic particle traps 306a include a magnet that provides a field capable of attracting magnetic particles such as particulate material generated by wear from friction involving the baseplate sealing surface 302. Magnetic particle traps 306a can further include, for example, a plating, coating, or other material containing the magnet. The magnetic particle traps 306a can be, for example, a magnetic disc or puck sized to correspond to the recess 304 that the magnetic particle trap 306a is installed into. In an embodiment, the magnetic particle traps 306a are provided as a coating applied in recesses 304. In an embodiment, the magnetic particle traps 306a are attached to recesses 304 by a mechanical connection and/or an adhesive. By being disposed in recesses 304, the magnetic particle traps 306a can draw particulate matter into the recesses 304, out of plane with paths into the internal space of the reticle container including baseplate 300. Accordingly, particulate entry into the internal space of the reticle container including baseplate 300 can be reduced.

Magnetic particle traps 306b can optionally be included in the internal space of the reticle container when baseplate 300 is joined with a corresponding cover. Magnetic particle trap 306b includes a magnet and can further include, for example, a plating, coating, or other material containing the magnet. The magnetic particle traps 306b can be provided inside of baseplate sealing surface 302. In an embodiment, magnetic particle trap 306b is continuous about an interior perimeter of the baseplate sealing surface 302. In an embodiment, magnetic particle trap 306b includes one or more segments each extending corresponding to a portion of the interior perimeter of baseplate sealing surface 302. In an embodiment, magnetic particle trap 306b is applied as a coating. In an embodiment, magnetic particle trap 306b is attached through a mechanical connection and/or an adhesive. In an embodiment, magnetic particle trap 306b is level with adjacent surfaces of baseplate 300 inside of baseplate sealing surface 302. In an embodiment, magnetic particle trap 306b is disposed in a recess relative to adjacent surfaces of baseplate 300. In an embodiment, magnetic particle trap 306b can project relative to the adjacent surfaces of baseplate 300.

When the optional magnetic particle traps 306a and/or b are included in the baseplate 300, the attractive force of the magnetic particle traps 306a and/or b included in baseplate 300 can be selected such that the attractive force does not interfere with separation of baseplate 300 from a corresponding cover. For example, the attractive force between magnetic particle traps 306a and/or b and the baseplate can be less than a weight of the baseplate 300, such that the baseplate 300 can separate from the cover when the cover is lifted or when support for the baseplate 300 is removed while cover is being retained in a tool.

Aspects:

It is understood that any of aspects 1-8 can be combined with any of aspects 9-14 or 15-20. It is understood that any of aspects 9-14 can be combined with any of aspects 15-20.

Aspect 1. An article, comprising a reticle container including:
a cover including a cover sealing surface; and
a baseplate including a baseplate sealing surface;
wherein the cover and the baseplate define an internal space configured to accommodate a reticle, and
the reticle container further includes one or more magnetic particle traps disposed on or in the cover, the baseplate, or a combination thereof;

Aspect 2. The article according to aspect 1, wherein the one or more magnetic particle traps include a plurality of depressions provided on one of the cover sealing surface or the baseplate sealing surface.

Aspect 3. The article according to aspect 2, wherein the other of the cover sealing surface or the baseplate sealing surface includes a plurality of projections, each projection configured to extend into one of the plurality of depressions.

Aspect 4. The article according to any of aspects 1-3, wherein the cover includes one or more filter openings, and the one or more magnetic particle traps are each disposed at one of the one or more filter openings.

Aspect 5. The article according to any of aspects 1-4, wherein the one or more magnetic particle traps are disposed within the internal space.

Aspect 6. The article according to any of aspects 1-5, wherein at least one of the cover sealing surface and the baseplate sealing surface includes a magnetic material.

Aspect 7. The reticle container according to aspect 6, wherein the magnetic material is included in a coating applied to the cover or the baseplate to form the cover sealing surface or the baseplate sealing surface.

Aspect 8. The reticle container according to any of aspects 1-7, wherein the magnetic particle traps are configured such that an attraction force between the magnetic particle trap and the cover or the baseplate is less than a weight of the baseplate.

Aspect 9. A method of containing a reticle, comprising placing the reticle in an internal space of a reticle container, the reticle container including a cover, a baseplate, and one or more magnetic particle traps each including a magnet, wherein the cover includes a cover sealing surface, the baseplate includes a baseplate sealing surface.

Aspect 10. The method according to aspect 9, further comprising capturing magnetic particles at the one or more magnetic particle traps.

Aspect 11. The method according to aspect 10, further comprising cleaning the magnetic particle traps by reducing an attraction between the magnet of each of the one or more magnetic particle traps and the magnetic particles.

Aspect 12. The method according to aspect 11, wherein cleaning the magnetic particle traps further includes applying a flow of gas to the magnetic particle traps.

Aspect 13. The method according to any of aspects 10-12, wherein one or both of the cover sealing surface and the baseplate sealing surface includes a magnetic material, and the magnetic particles result from wearing at the one or both of the cover sealing surface and the baseplate sealing surface including the magnetic material.

Aspect 14. The method according to any of aspects 9-13, further comprising separating the cover and the baseplate by supporting the cover and allowing the baseplate to drop.

Aspect 15. A method of manufacturing a reticle container, comprising:
providing a cover having a cover sealing surface;
providing a baseplate having a baseplate sealing surface; and
providing one or more magnetic particle traps on or in the cover, the baseplate, or a combination thereof.

Aspect 16. The method according to aspect 15, further comprising providing magnetic material at one or both of the cover sealing surface and the baseplate sealing surface.

Aspect 17. The method according to aspect 16, wherein the providing magnetic material at the one or both of the cover sealing surface and the baseplate sealing surface includes applying a coating containing the magnetic material to the one or both of the cover sealing surface and the baseplate sealing surface.

Aspect 18. The method according to any of aspects 15-17, wherein the providing one or more magnetic particle traps includes providing a plurality of depressions in one of the cover sealing surface or the baseplate sealing surface and disposing a magnet in each of the plurality of depressions.

Aspect 19. The method according to any of aspects 15-18, wherein the cover includes one or more filter openings, and providing the one or more magnetic particle traps includes disposing the each of the one or more magnetic particle traps at one of the one or more filter openings.

Aspect 20. The method according to any of aspects 15-19, wherein providing the one or more magnetic particle traps includes disposing each of the one or more magnetic particle traps on a surface of the cover or the baseplate defining the internal space of the reticle container.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

1. An article, comprising a reticle container including:
a cover including a cover sealing surface; and
a baseplate including a baseplate sealing surface;
wherein the cover and the baseplate define an internal space configured to accommodate a reticle, and
the reticle container further includes one or more magnetic particle traps disposed on or in the cover, the baseplate, or a combination thereof;

2. The article of claim 1, wherein the one or more magnetic particle traps include a plurality of depressions provided on one of the cover sealing surface or the baseplate sealing surface.

3. The article of claim 2, wherein the other of the cover sealing surface or the baseplate sealing surface includes a plurality of projections, each projection configured to extend into one of the plurality of depressions.

4. The article of claim 1, wherein the cover includes one or more filter openings, and the one or more magnetic particle traps are each disposed at one of the one or more filter openings.

5. The article of claim 1, wherein the one or more magnetic particle traps are disposed within the internal space.

6. The article of claim 1, wherein at least one of the cover sealing surface and the baseplate sealing surface includes a magnetic material.

7. The reticle container of claim 6, wherein the magnetic material is included in a coating applied to the cover or the baseplate to form the cover sealing surface or the baseplate sealing surface.

8. The reticle container of claim 1, wherein the magnetic particle traps are configured such that an attraction force between the magnetic particle trap and the cover or the baseplate is less than a weight of the baseplate.

9. A method of containing a reticle, comprising placing the reticle in an internal space of a reticle container, the reticle container including a cover, a baseplate, and one or more magnetic particle traps each including a magnet, wherein the cover includes a cover sealing surface, the baseplate includes a baseplate sealing surface.

10. The method of claim 9, further comprising capturing magnetic particles at the one or more magnetic particle traps.

11. The method of claim 10, further comprising cleaning the magnetic particle traps by reducing an attraction between the magnet of each of the one or more magnetic particle traps and the magnetic particles.

12. The method of claim 11, wherein cleaning the magnetic particle traps further includes applying a flow of gas to the magnetic particle traps.

13. The method of claim 10, wherein one or both of the cover sealing surface and the baseplate sealing surface includes a magnetic material, and the magnetic particles result from wearing at the one or both of the cover sealing surface and the baseplate sealing surface including the magnetic material.

14. The method of claim 9, further comprising separating the cover and the baseplate by supporting the cover and allowing the baseplate to drop.

15. A method of manufacturing a reticle container, comprising:
providing a cover having a cover sealing surface;
providing a baseplate having a baseplate sealing surface; and
providing one or more magnetic particle traps on or in the cover, the baseplate, or a combination thereof.

16. The method of claim 15, further comprising providing magnetic material at one or both of the cover sealing surface and the baseplate sealing surface.

17. The method of claim 16, wherein the providing magnetic material at the one or both of the cover sealing surface and the baseplate sealing surface includes applying a coating containing the magnetic material to the one or both of the cover sealing surface and the baseplate sealing surface.

18. The method of claim 15, wherein the providing one or more magnetic particle traps includes providing a plurality of depressions in one of the cover sealing surface or the baseplate sealing surface and disposing a magnet in each of the plurality of depressions.

19. The method of claim 15, wherein the cover includes one or more filter openings, and providing the one or more magnetic particle traps includes disposing the each of the one or more magnetic particle traps at one of the one or more filter openings.

20. The method of claim 15, wherein providing the one or more magnetic particle traps includes disposing each of the one or more magnetic particle traps on a surface of the cover or the baseplate defining the internal space of the reticle container.
